(19) United States
(12) Patent Application Publication
(10) Pub. No.: US 2013/0330899 A1
(43) Pub. Date: Dec. 12, 2013

(54) PREVENTING FULLY SILICIDED FORMATION IN HIGH-K METAL GATE PROCESSING

(71) Applicants: Huiming Bu, Millwood, NY (US); Ming Cai, Hopewell Junction, NY (US); Kevin K. Chan, Staten Island, NY (US); Dechao Guo, Fishkill, NY (US); Ravikumar Ramachandran, Pleasantville, NY (US); Liyang Song, Wappingers Falls, NY (US); Chun-Chen Yeh, Clifton Park, NY (US)

(72) Inventors: Huiming Bu, Millwood, NY (US); Ming Cai, Hopewell Junction, NY (US); Kevin K. Chan, Staten Island, NY (US); Dechao Guo, Fishkill, NY (US); Ravikumar Ramachandran, Pleasantville, NY (US); Liyang Song, Wappingers Falls, NY (US); Chun-Chen Yeh, Clifton Park, NY (US)

(73) Assignee: INTERNATIONAL BUSINESS MACHINES CORPORATION, Armonk, NY (US)

(21) Appl. No.: 13/527,063

(22) Filed: Jun. 19, 2012

Related U.S. Application Data
(63) Continuation of application No. 13/494,312, filed on Jun. 12, 2012.

(51) Int. Cl. H01L 21/336; H01L 21/04

(52) U.S. Cl. 438/300; 438/510; 257/E21.409; 257/E21.04

(57) ABSTRACT

A method of forming gate stack structure for a transistor device includes forming a gate dielectric layer over a substrate; forming a first silicon gate layer over the gate dielectric layer; forming a dopant-rich monolayer over the first silicon gate layer; and forming a second silicon gate layer over the dopant-rich monolayer, wherein the dopant-rich monolayer prevents silicidation of the first silicon gate layer during silicidation of the second silicon gate layer.

### PRIORITY

This application is a continuation of U.S. patent application Ser. No. 13/494,312, filed Jun. 12, 2012, the contents of which are incorporated herein by reference in their entirety.

### BACKGROUND

The present invention relates generally to semiconductor device manufacturing and, more particularly, to preventing fully silicided (FUSI) formation in high-k metal (HKMG) gate processing.

Field effect transistors (FETs) are widely used in the electronics industry for switching, amplification, filtering, and other tasks related to both analog and digital electrical signals. Most common among these are metal-oxide-semiconductor field effect transistors (MOSFET or MOS), in which a gate structure is energized to create an electric field in an underlying channel region of a semiconductor body, by which electrons are allowed to travel through the channel between a source region and a drain region of the semiconductor body. Complementary MOS (CMOS) devices have become widely used in the semiconductor industry, wherein both n-type and p-type (NFET and PFET) FETs are used to fabricate logic and other circuitry.

The source and drain regions of an FET are typically formed by adding dopants to targeted regions of a semiconductor body on either side of the channel. A gate structure is formed above the channel, which includes a gate dielectric located over the channel and a gate conductor above the gate dielectric. The gate dielectric is an insulator material, which prevents large leakage currents from flowing into the channel when a voltage is applied to the gate conductor, while allowing the applied gate voltage to set up a transverse electric field in the channel region in a controllable manner. Conventional MOS transistors typically include a gate dielectric formed by depositing or by growing silicon dioxide (SiO₂) or silicon oxynitride (SiON) over a silicon wafer surface, with doped polysilicon formed over the SiO₂ to act as the gate conductor.

Continuing trends in semiconductor device manufacturing include reduction in electrical device feature sizes (i.e., scaling), as well as improvements in device performance in terms of device switching speed and power consumption. MOS transistor performance may be improved by reducing the distance between the source and the drain regions under the gate conductor of the device, known as the gate or channel length, and by reducing the thickness of the layer of gate dielectric that is formed over the semiconductor surface. However, there are electrical and physical limitations on the extent to which the thickness of SiO₂ gate dielectrics can be reduced. For example, thin SiO₂ gate dielectrics are prone to gate tunneling leakage currents resulting from direct tunneling of electrons through the thin gate dielectric.

Accordingly, recent MOS and CMOS transistor scaling efforts have focused on high-k dielectric materials having dielectric constants greater than that of SiO₂ (e.g., greater than about 3.9). High-k dielectric materials can be formed in a thicker layer than scaled SiO₂, and yet still produce equivalent field effect performance. The relative electrical performance of such high-k dielectric materials is often expressed in terms equivalent oxide thickness (EOT), since the high-k material layer may be thicker, while still providing the equivalent electrical effect of a much thinner layer of SiO₂. Because the dielectric constant “k” is higher than silicon dioxide, a thicker high-k dielectric layer can be employed to mitigate tunneling leakage currents, while still achieving the equivalent electrical performance of a thinner layer of thermally grown SiO₂.

### SUMMARY

In one aspect, a method of forming gate stack structure for a transistor device includes forming a gate dielectric layer over a substrate; forming a first silicon gate layer over the gate dielectric layer; forming a dopant-rich monolayer over the first silicon gate layer; and forming a second silicon gate layer over the dopant-rich monolayer, wherein the dopant-rich monolayer prevents silicidation of the first silicon gate layer during silicidation of the second silicon gate layer.

In another aspect, a method of forming a transistor device includes forming a gate dielectric layer over a substrate; forming a first silicon gate layer over the gate dielectric layer; forming a dopant-rich monolayer over the first silicon gate layer; forming a second silicon gate layer over the dopant-rich monolayer; forming a hardmask layer over the second silicon gate layer; patterning the gate dielectric layer, the first silicon gate layer, the dopant-rich monolayer, the second silicon gate layer and the hardmask layer so as to form a patterned gate stack structure; forming source and drain regions in the substrate and adjacent the patterned gate stack structure; removing the hardmask layer to expose the second silicon gate layer; and forming silicide contacts on the source and drain regions, and the second silicon gate layer, wherein the dopant-rich monolayer prevents silicidation of the first silicon gate layer during silicidation of the second silicon gate layer.

### BRIEF DESCRIPTION OF THE SEVERAL VIEWS OF THE DRAWINGS

Referring to the exemplary drawings wherein like elements are numbered alike in the several Figures:

FIGS. 1(a) through 1(i) are cross sectional views illustrating a process flow for forming a high-K, metal gate (HKMG) transistor device, in which:

FIG. 1(a) illustrates the formation of a high-K dielectric layer over a semiconductor substrate;

FIG. 1(b) illustrates the formation of a metal gate layer over the high-K dielectric layer of FIG. 1(a);

FIG. 1(c) illustrates the formation of a silicon gate layer over the metal gate layer of FIG. 1(b);

FIG. 1(d) illustrates the formation of a hardmask layer over the silicon gate layer of FIG. 1(c);

FIG. 1(e) illustrates patterning of the gate stack layers of FIG. 1(d);

FIG. 1(f) illustrates the formation of sidewall spacers on the patterned gate stack of FIG. 1(e);

FIG. 1(g) illustrates the formation of epitaxially grown source and drain regions in the substrate of FIG. 1(f);

FIG. 1(h) illustrates the removal of the hardmask layer from the patterned gate stack of FIG. 1(g);

FIG. 1(i) illustrates the formation of silicide contacts on the gate, source and drain regions of FIG. 1(h);

FIGS. 2(a) through 2(k) are cross sectional views illustrating a process flow for forming a high-K, metal gate (HKMG) transistor device in accordance with an exemplary embodiment, in which:

FIG. 2(a) illustrates the formation of a high-K dielectric layer over a semiconductor substrate;

FIG. 2(b) illustrates the formation of a metal gate layer over the high-K dielectric layer of FIG. 2(a);

FIG. 2(c) illustrates the formation of a first silicon gate layer over the metal gate layer of FIG. 2(b);

FIG. 2(d) illustrates the formation of a dopant-rich monolayer over the first silicon gate layer of FIG. 2(c);

FIG. 2(e) illustrates the formation of a second silicon gate layer over the monolayer of FIG. 2(d);

FIG. 2(f) illustrates the formation of a hardmask layer over the second silicon gate layer of FIG. 2(e);

FIG. 2(g) illustrates patterning of the gate stack layers of FIG. 2(f);

FIG. 2(h) illustrates the formation of sidewall spacers on the patterned gate stack of FIG. 2(g);

FIG. 2(i) illustrates the formation of epitaxially grown source and drain regions in the substrate of FIG. 2(h);

FIG. 2(j) illustrates the removal of the hardmask layer from the patterned gate stack of FIG. 2(h); and

FIG. 2(k) illustrates the formation of silicide contacts on the gate, source and drain regions of FIG. 2(j), wherein the dopant-rich monolayer prevents the silicon gate material from becoming fully silicided.

### DETAILED DESCRIPTION

With respect to high-k metal gate (HKMG) technology, the two main approaches for introducing a metal gate into the standard CMOS process flow are a “gate first” process or a “gate last” process. The latter is also referred to as a “replacement gate” or replacement metal gate (RMG) process. In a gate first process, high-k dielectric and metal processing is completed prior to polysilicon gate deposition. The metal gate material is subtractively etched along with the polysilicon gate material prior to source and drain formation. Once the source and drain regions are formed, silicide contacts are formed on the gate, source and drain regions.

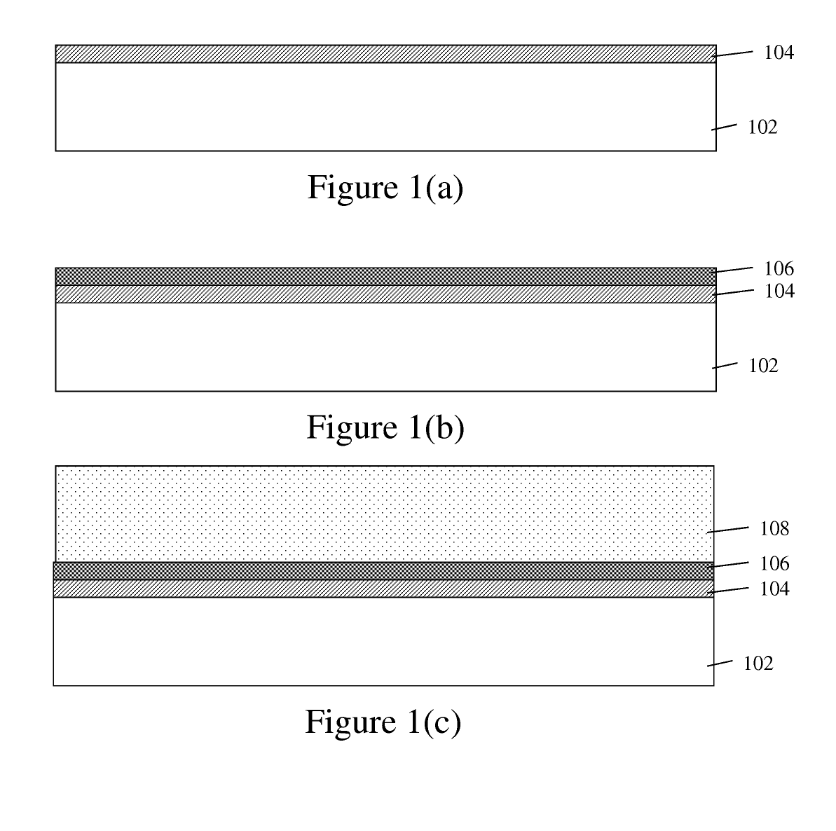

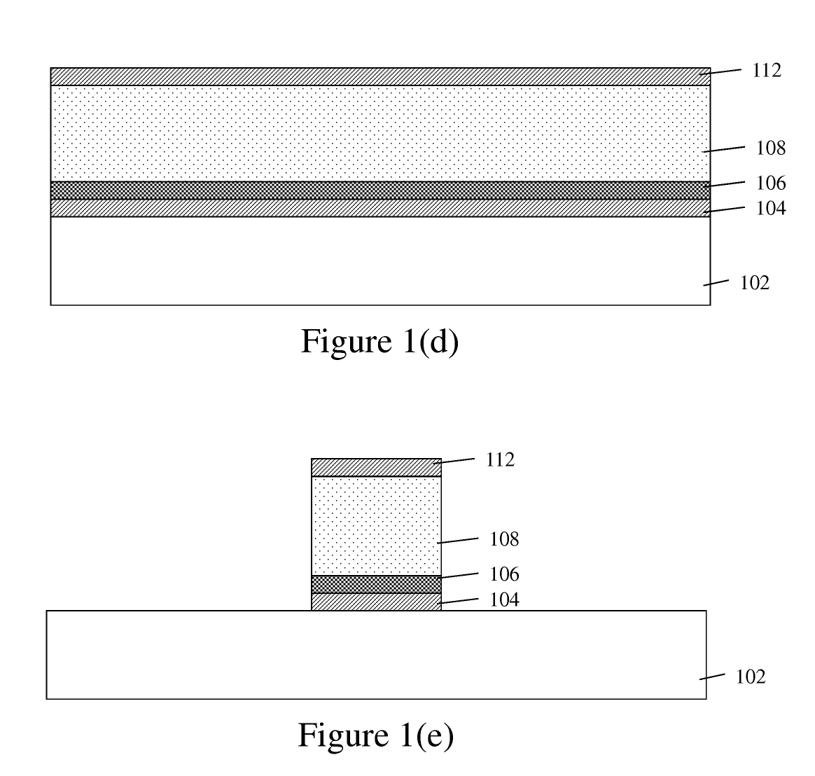

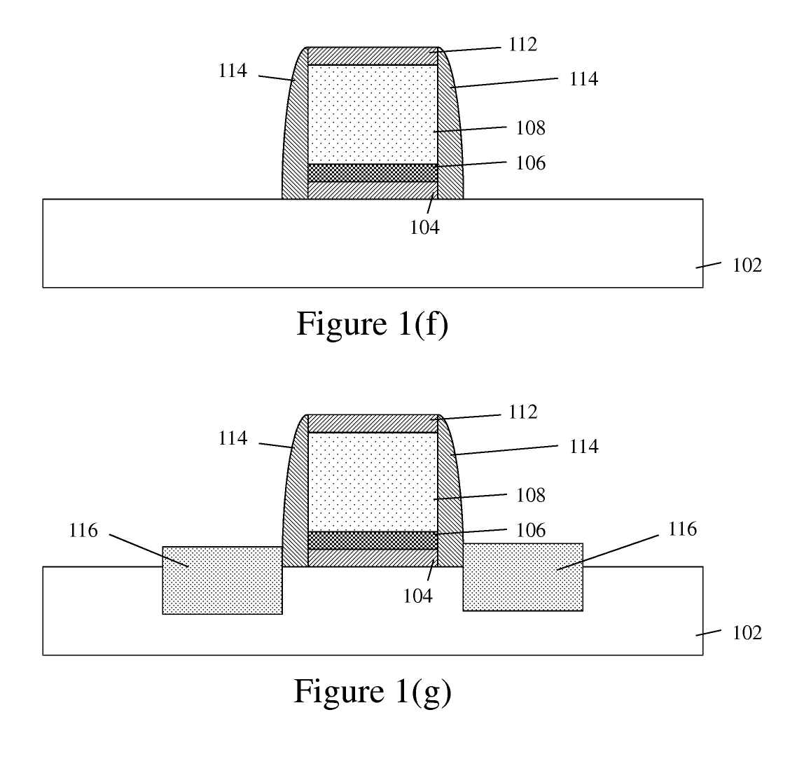

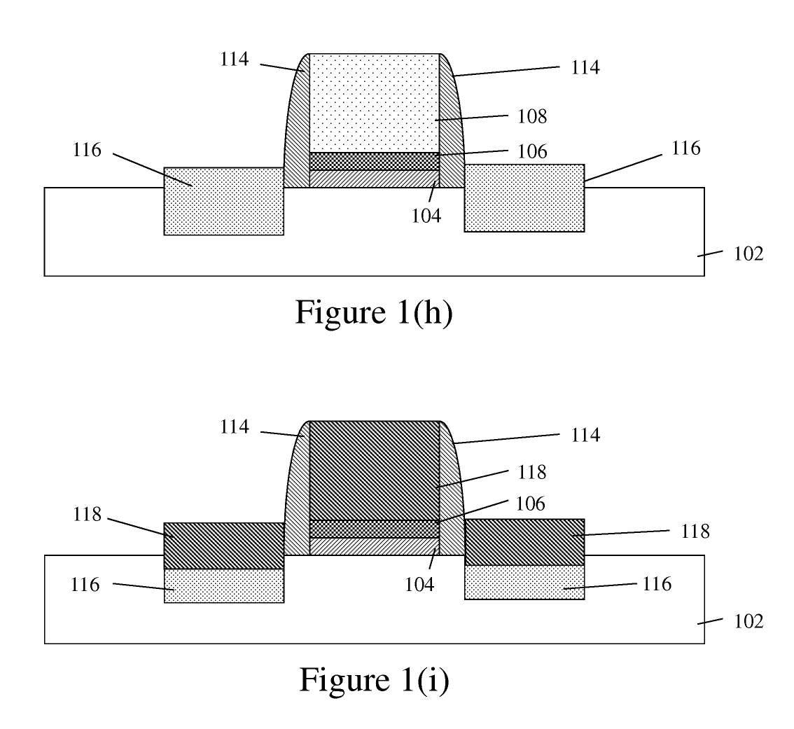

Referring initially to FIGS. 1(a) through 1(i), there is shown a series of cross sectional views illustrating a process flow for forming a high-K, metal gate (HKMG) transistor device. Beginning in FIG. 1(a), a semiconductor substrate 102 has a high-K dielectric layer 104 formed thereon. The semiconductor substrate 102 includes a semiconductor material, which may be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Where the semiconductor material of the semiconductor substrate 102 is a single crystalline silicon-containing semiconductor material, the single crystalline silicon-containing semiconductor material may be selected from single crystalline silicon, a single crystalline silicon carbon alloy, a single crystalline silicon germanium alloy, and a single crystalline silicon germanium carbon alloy.

The semiconductor material of the semiconductor substrate 102 may be appropriately doped either with p-type dopant atoms or with n-type dopant atoms. The dopant concentration of the semiconductor substrate 102 may range from about 1.0×10¹⁵ atoms/cm³ to about 1.0×10¹⁹ atoms/cm³, and more specifically from about 1.0×10¹⁶ atoms/cm³ to about 3.0×10¹⁸ atoms/cm³, although lesser and greater dopant concentrations are contemplated herein also. In addition, the semiconductor substrate 102 may be a bulk substrate, a semiconductor-on-insulator or silicon-on-insulator (SOI) substrate, or a hybrid substrate.

The high-K dielectric layer 104 may include a dielectric metal oxide having a dielectric constant that is greater than the dielectric constant (7.5) of silicon nitride, and may be formed by methods well known in the art including, for example, chemical vapor deposition (CVD), ALD, molecular beam deposition (MBD), pulsed laser deposition (PLD), liquid source misted chemical deposition (LSMCD), etc. In an exemplary embodiment, the dielectric metal oxide of the high-k dielectric layer 118 includes a metal and oxygen, and optionally nitrogen and/or silicon. Specific examples of high-k dielectric materials include, but are not limited to: HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from 0.5 to 3 and each value of y is independently from 0 to 2. The thickness of the high-k dielectric layer 104 may be from about 1 nm to about 10 nm, and more specifically from about 1.5 nm to about 3 nm.

As shown in FIG. 1(b), a metal gate layer 106 is then formed over the high-K dielectric layer 104. The metal gate layer 106, while schematically illustrated as a single layer in FIG. 1(b), may be a metal gate material stack that includes one or more layers of metal materials such as, for example, Al, Ta, TaN, W, WN, Ti and TiN, having an appropriate workfunction depending on whether the transistor is an NFET or a PFET device.

In one specific embodiment of an NFET device, the metal gate layer 106 may include workfunction setting metal layers selected to set the workfunction around the silicon conduction band edge. Such workfunction setting metal layers may include, for example, optional layers of about 10 Å to about 30 Å thick titanium nitride and about 10 Å to about 30 Å thick tantalum nitride, followed by a non-optional about 10 Å to about 40 Å thick layer of titanium aluminum, which together make up a workfunction setting metal layer portion of the metal gate layer 106. Alternatively, titanium aluminum nitride, tantalum aluminum, tantalum aluminum nitride, hafnium silicon alloy, hafnium nitride, or tantalum carbide may be used in the workfunction setting metal layer portion in lieu of the titanium aluminum.

In one specific embodiment of a PFET device, the metal gate layer 106 may include workfunction setting metal layers selected to set the workfunction around the silicon valence band edge. Here, such workfunction setting metal layers may include, for example, optional layers of about 10 Å to about 30 Å thick titanium nitride and about 10 Å to about 30 Å thick tantalum nitride, followed by non-optional layers of about 30 Å to about 70 Å thick titanium nitride and about 10 Å to about 40 Å thick layer of titanium aluminum, which together make up a workfunction setting metal layer portion of the metal gate layer 106. Alternatively, tungsten, tantalum nitride, ruthenium, platinum, rhenium, iridium, or palladium may be used in the workfunction setting metal layer portion in lieu of the titanium nitride and titanium aluminum nitride, tantalum aluminum, tantalum aluminum nitride, hafnium silicon alloy, hafnium nitride, or tantalum carbide may be deposited instead of the titanium aluminum.

Regardless of the specific workfunction setting metal layers used in either an NFET or a PFET device, a remainder of the metal gate layer 106 may include a fill metal such as aluminum, titanium-doped aluminum, tungsten or copper. Proceeding to FIG. 1(c), a doped silicon (e.g., amorphous silicon, polysilicon) gate layer 108 is formed over the metal gate layer 106, such as by chemical vapor deposition (CVD), for example. This is followed by deposition of a hardmask layer 112 (e.g., silicon nitride) over the silicon gate layer 108, as shown in FIG. 1(d).

Upon completion of the gate stack materials, the device is then subjected to a photolithographic patterning process, including photoresist material (not shown) deposition, development and etching, etc., so as to form a patterned gate stack structure shown in FIG. 1(e). In FIG. 1(f), sidewall spacers 114 (e.g., a nitride material) are formed on the patterned gate stack in preparation of source and drain region definition. The source and drain regions may be formed by dopant implantation of the substrate 102 as known in the art. Alternatively, source and drain regions 116 may be epitaxially grown in the substrate 102 adjacent the gate structure as also known in the art. For example, a silicon substrate 102 may be etched in regions corresponding to the source and drain locations, followed by epitaxial growth of silicon germanium (eSiGe) source and drain regions 116, as shown in FIG. 1(g).

In FIG. 1(h), a directional etch is used to remove the hardmask layer 112 from the patterned gate stack of FIG. 1(g), and expose a top surface of the silicon gate layer 108. At this point, the device is readied for silicide contact formation. As known in the art, a self-aligned silicide or “salicide” process involves blanket deposition of a refractory metal layer (e.g., nickel, cobalt, platinum, titanium, tungsten, etc.) over both insulating and semiconducting portions of the device. A high-temperature anneal causes the refractory metal to react with silicon, thereby creating a low resistance silicide contact. The metal does not react with the insulating materials of the device, and as such can be selectively removed from the device following the anneal, thereby leaving the silicide contacts atop the gate, source and drain regions of the transistor, as shown in FIG. 1(i).

For future CMOS technologies, gate height reduction will become more desirable in order to reduce parasitic capacitance the increase the speed of devices such a ring oscillators. In a gate first integration scheme where gate height is reduced, there is the concern that the gate may become fully silicided (FUSI), such as shown in FIG. 1(i). That is, substantially the entire height of the silicon layer 108 of FIG. 1(h) is converted to silicide (e.g., nickel silicide (NiSi)). Although there are certain advantages to FUSI gates (e.g., greater workfunction range), when the gate height is reduced, the silicided gate metal may encroach toward the source drain regions. This in turn leaves the potential for gate-to-source/drain shorting or other device variability concerns.

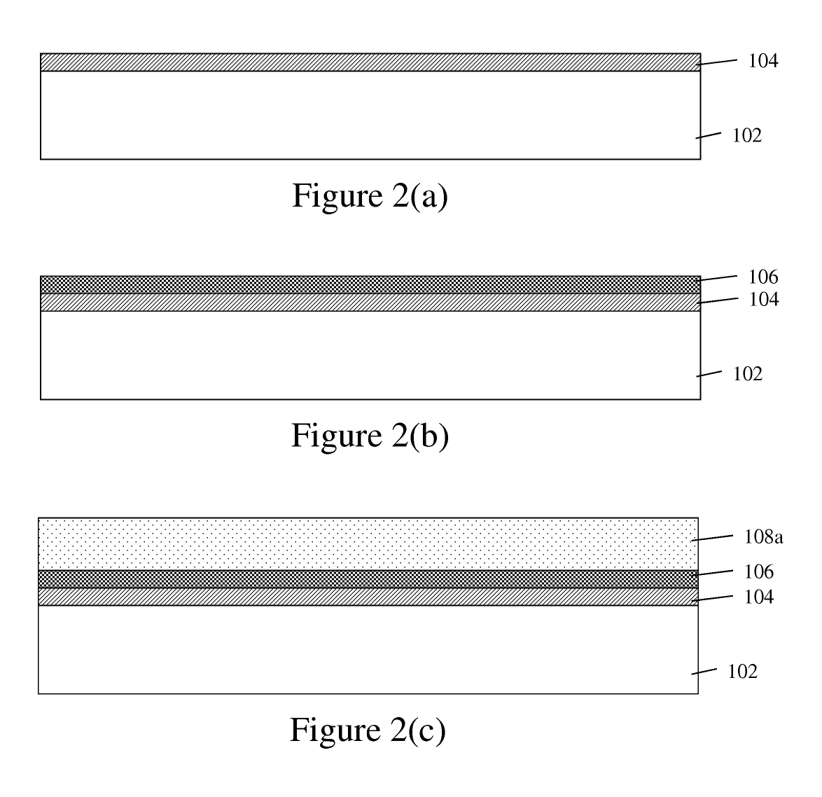

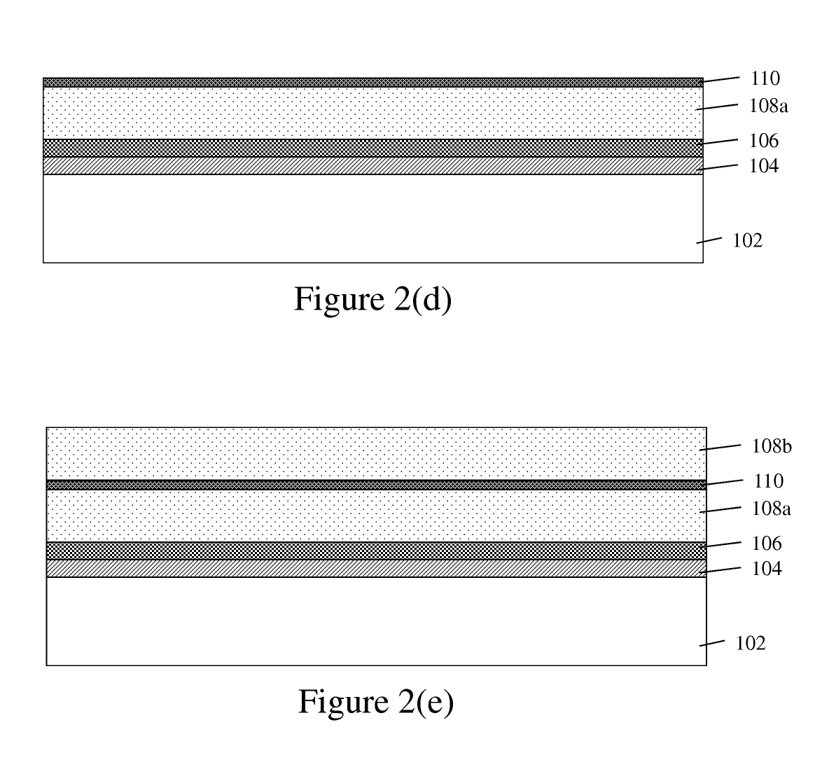

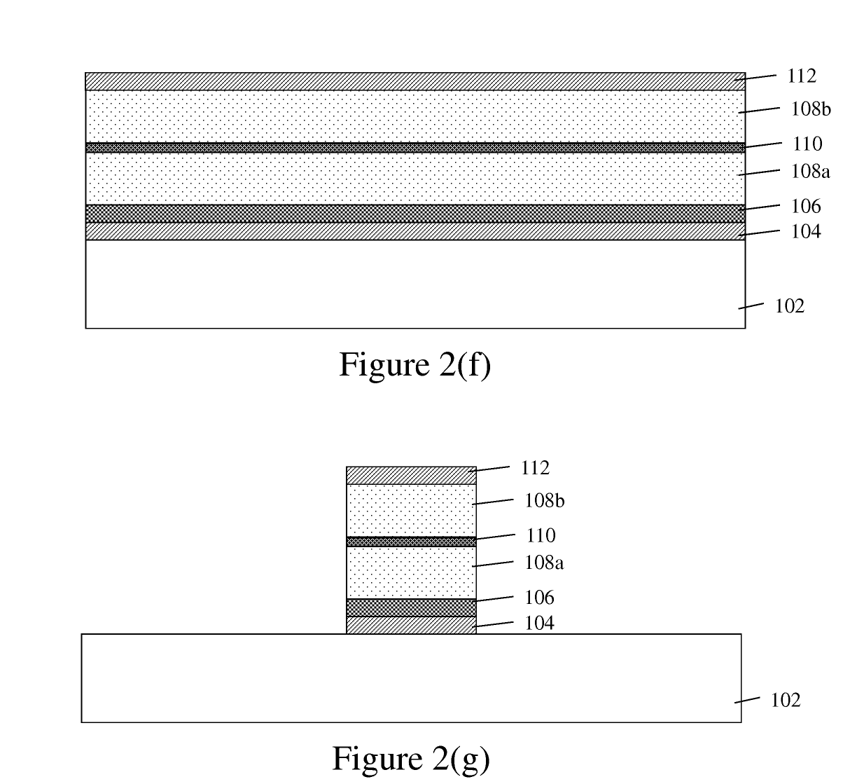

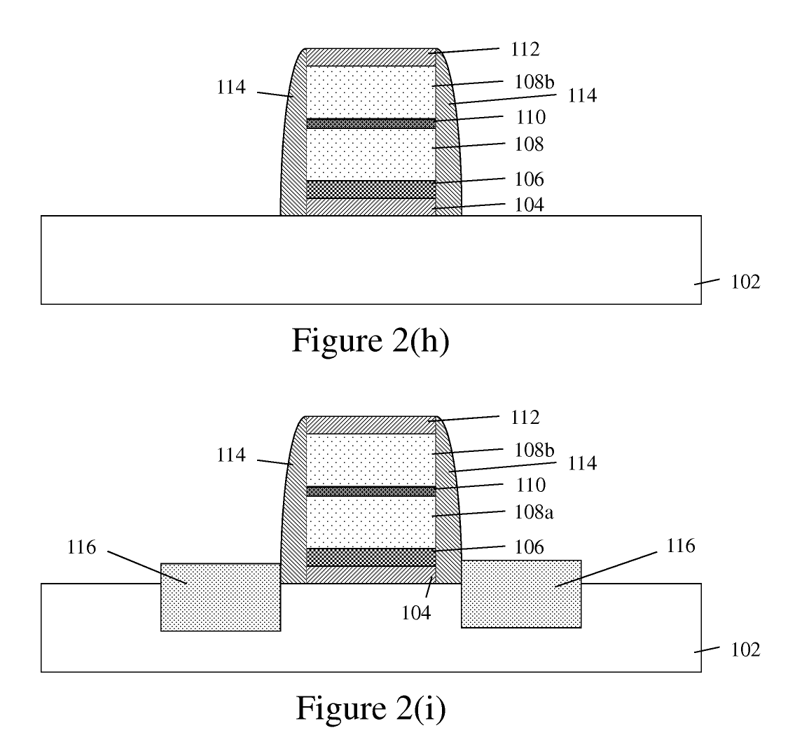

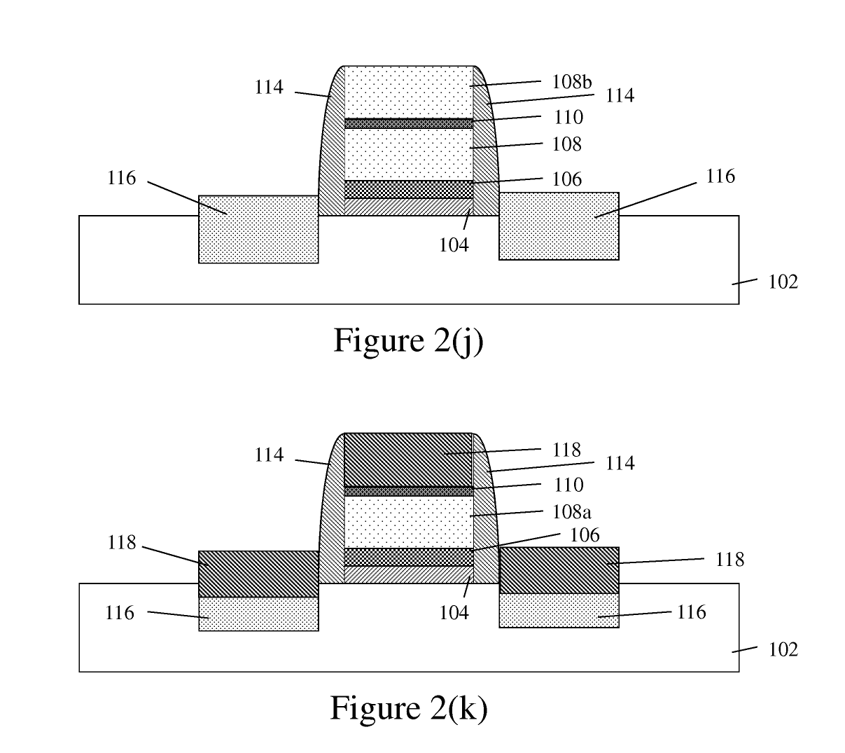

Accordingly, FIGS. 2(a) through 2(k) are cross sectional views illustrating a process flow for forming an HKMG transistor device in accordance with an exemplary embodiment, in which FUSI formation is prevented. In the figures, similar reference numerals are used for similar elements for ease of description. In the illustrated embodiment, FIGS. 2(a) and 2(b) are substantially similar to those of FIGS. 1(a) and 1(b), with a semiconductor substrate 102 having a high-K dielectric layer 104 formed thereon, followed by a metal gate layer 106 formed over the high-K dielectric layer 104.

In FIG. 2(c), a first doped silicon gate layer 108a (e.g., amorphous silicon, polysilicon) is formed over the metal gate layer 106. Here, the height of the first doped silicon gate layer 108a is less than that of the intended final gate stack height. In one embodiment, the first doped silicon gate layer 108a may be deposited at a thickness ranging from about 50 Å to about 70 Å. Then, as illustrated in FIG. 2(d), a dopant-rich monolayer 110 is formed over the first silicon gate layer 108a. The monolayer 110 is selected from a material such as, for example, boron, phosphorous, arsenic, etc. that will prevent penetration of silicide metal formation at the interface of the monolayer 110 and a subsequently formed second silicon layer. In one exemplary embodiment, the monolayer comprises a boron doped monolayer having a thickness ranging from about 7 Å to about 30 Å, and at a dopant concentration of about 1.0×10²¹ atoms/cm³ or higher.

FIG. 2(e) illustrates the formation of a second silicon gate layer 108b over the monolayer 110. It should be noted at this point that the various layers in the figures are not intended to be shown to scale, and are only for illustrative purposes. In an exemplary embodiment, the second doped silicon gate layer 108b may be deposited at a thickness ranging from about 200 Å to about 250 Å. In one implementation, the gate stack sequence 108a/110/108b may be formed by amorphous or polysilicon deposition for a period of time corresponding the desired thickness of the first doped silicon gate layer 108a, followed by introduction of the desired monolayer dopant 110 with the silicon material, followed by removal of the dopant material and continued silicon deposition to the desired thickness of the second doped silicon gate layer 108b.

At this point, the processing operations in FIGS. 2(f) through 2(j) are substantially similar to those shown in FIGS. 1(d) through 1(h). That is, FIG. 2(f) illustrates the formation of a hardmask layer 112 over the second silicon gate layer 108b, FIG. 2(g) illustrates patterning of the gate stack layers of FIG. 2(f), and FIG. 2(h) illustrates the formation of sidewall spacers 114 on the patterned gate stack of FIG. 2(g). In addition, FIG. 2(i) illustrates the formation of epitaxially grown source and drain regions 116 in the substrate of FIG. 2(h), while FIG. 2(j) illustrates the removal of the hardmask layer 112 from the patterned gate stack of FIG. 2(h).

However, as then shown in FIG. 2(k), it will be noted that during formation of silicide contacts 118 on the gate, source and drain regions, the dopant-rich monolayer 110 prevents the first doped silicon gate layer 108a from becoming fully silicided. As a result, a reduced gate height transistor structure has benefit of both low resistance silicide contact formation, but is not fully silicided so as to alleviate concerns about processing variations that may otherwise cause, for example, encroachment of the gate silicide material to the source and drain regions. A sufficiently doped monolayer (e.g., 1.0×10²¹ atoms/cm³ of boron) has been shown to prevent NiSi penetration even after a relatively high temperature process, such as a laser implemented, dynamic surface anneal (DSA) that heats the wafer to a temperature of about 950° C. for a duration of about 3 milliseconds.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method of forming gate stack structure for a transistor device, the method comprising:
forming a gate dielectric layer over a substrate;
forming a first silicon gate layer over the gate dielectric layer;
forming a dopant-rich monolayer, selected from the group consisting of boron, phosphorous, and arsenic, over the first silicon gate layer; and
forming a second silicon gate layer over the dopant-rich monolayer, wherein the dopant-rich monolayer prevents silicidation of the first silicon gate layer during silicidation of the second silicon gate layer.

2. (canceled)

3. The method of claim 1, wherein the dopant-rich monolayer comprises boron having a dopant concentration of about 1.0×10²¹ atoms/cm³ or higher.

4. The method of claim 1, wherein:
forming the first silicon gate layer comprises depositing amorphous silicon at thickness ranging from about 50 angstroms (Å) to about 70 Å;
forming the dopant-rich monolayer over the first silicon gate layer comprises introducing boron having a dopant concentration of about 1.0×10²¹ atoms/cm³ or higher to a thickness from about 7 Å to about 30 Å; and
forming a second silicon gate layer over the dopant-rich monolayer comprises depositing amorphous silicon at thickness ranging from about 200 angstroms (Å) to about 250 Å.

5. The method of claim 1, wherein the gate dielectric layer comprises a high-K dielectric layer having a dielectric constant that is greater than the dielectric constant of silicon nitride.

6. The method of claim 5, further comprising forming a metal gate layer between the high-K dielectric layer and the first silicon gate layer.

7. A method of forming a transistor device, the method comprising:
forming a gate dielectric layer over a substrate;
forming a first silicon gate layer over the gate dielectric layer;
forming a dopant-rich monolayer, selected from the group consisting of boron, phosphorous, and arsenic, over the first silicon gate layer;
forming a second silicon gate layer over the dopant-rich monolayer;
forming a hardmask layer over the second silicon gate layer;
patterning the gate dielectric layer, the first silicon gate layer, the dopant-rich monolayer, the second silicon gate layer and the hardmask layer so as to form a patterned gate stack structure;
forming source and drain regions in the substrate and adjacent the patterned gate stack structure;
removing the hardmask layer to expose the second silicon gate layer; and
forming silicide contacts on the source and drain regions, and the second silicon gate layer, wherein the dopant-rich monolayer prevents silicidation of the first silicon gate layer during silicidation of the second silicon gate layer.

8. (canceled)

9. The method of claim 7, wherein the dopant-rich monolayer comprises boron having a dopant concentration of about 1.0×10²¹ atoms/cm³ or higher.

10. The method of claim 7, wherein:
forming the first silicon gate layer comprises depositing amorphous silicon at a thickness ranging from about 50 angstroms (Å) to about 70 Å;
forming the dopant-rich monolayer over the first silicon gate layer comprises introducing boron having a dopant concentration of about 1.0×10²¹ atoms/cm³ or higher to a thickness from about 7 Å to about 30 Å; and
forming a second silicon gate layer over the dopant-rich monolayer comprises depositing amorphous silicon at a thickness ranging from about 200 angstroms (Å) to about 250 Å.

11. The method of claim 7, wherein the gate dielectric layer comprises a high-K dielectric layer having a dielectric constant that is greater than the dielectric constant of silicon nitride.

12. The method of claim 11, further comprising forming a metal gate layer between the high-K dielectric layer and the first silicon gate layer.

13. The method of claim 7, wherein forming source and drain regions comprises epitaxially growing the source and drain regions.

14. The method of claim 7, wherein the silicide contacts comprise nickel silicide.

15. The method of claim 14, wherein forming the silicide contacts comprises performing a dynamic surface anneal (DSA) that heats the substrate to a temperature of about 950° C. for a duration of about 3 milliseconds.
